(19) United States
(12) Patent Application Publication
(10) Pub. No.: US 2015/0255750 A1
(43) Pub. Date: Sep. 10, 2015

(54) Package Substrate, OLED Display Panel and Manufacturing Method Thereof, and Display Apparatus

(71) Applicant: BOE Technology Group Co., Ltd., Beijing (CN)

(72) Inventors: Zhongyuan Sun, Beijing (CN); Wei Guo, Beijing (CN)

(73) Assignee: BOE Technology Group Co., Ltd., Beijing (CN)

(21) Appl. No.: 14/235,614

(22) PCT Filed: Sep. 18, 2013
(86) PCT No.: PCT/CN13/83743

§ 371 Date: Jan. 28, 2014

(30) Foreign Application Priority Data
Jun. 28, 2013 (CN) 201310269728.X

(51) Int. Cl. H01L 51/52; H01L 27/32; H01L 51/56

(52) U.S. Cl. CPC H01L 51/5259; H01L 51/56; H01L 51/5246; H01L 27/3244; H01L 2251/558; H01L 2227/323

(57) ABSTRACT

A package substrate for packaging OLED devices, an OLED display panel and a manufacturing method thereof, and a display apparatus are provided. The package substrate comprises a first base substrate and a desiccant layer provided on the first base substrate, wherein the desiccant layer comprises desiccant particles and a glue layer for fixing the desiccant particles. The OLED display panel comprises the above package substrate and an array substrate, wherein the array substrate comprises OLED devices, and the array substrate and the package substrate are aligned and assembled into the OLED display panel. The method for manufacturing an OLED display panel comprises: forming a desiccant layer on a first base substrate to prepare a package substrate; forming OLED devices on a second base substrate to prepare an array substrate; aligning and assembling the array substrate and the package substrate. The display apparatus comprises the above OLED display panel.

### TECHNICAL FIELD

The present invention relates to the field of display technology, and particularly, to a package substrate, an OLED display panel and a manufacturing method thereof, and a display apparatus.

### BACKGROUND ART

Currently, Organic Light-Emitting Diode (OLED) devices have become the next generation of display devices with competitiveness and development prospect for their many advantages such as all solid state structure, high brightness, full viewing angle, quick response, wide operating temperature range, the ability of flexible display, etc. The organic light-emitting material and the cathode material in OLED devices are particularly sensitive to water and oxygen, thus the life of OLED devices will be affected if the humidity or the oxygen content is too high. In order to achieve a longer life, it is usually required that the permeability to water and the permeability to oxygen are less than 5×10⁻⁶ g/m²·day and 10⁻³ m³/m²·day respectively, which makes higher requirements for the package of OLED devices.

An existing package is back cover package, as shown in FIG. 1. In FIG. 1, the upper substrate is a package substrate 1 comprising a first base substrate 14, wherein a sheet-like desiccant 11 is attached to the inner surface of the first base substrate 14, and the sheet-like desiccant 11 usually comprises a sheet-like substrate, a sheet-like desiccant layer, an adhesive layer provided on one side of the sheet-like substrate for adhering the first base substrate 14 and an adhesive layer provided on the other side of the sheet-like substrate for adhering the sheet-like desiccant layer. With respect to manufacturing process, in order to ensure uniform thickness of the sheet-like desiccant layer, the thickness of the sheet-like desiccant layer usually should be thicker relatively, thereby the total thickness of the sheet-like desiccant 11 is large. Therefore, in order to eliminate surface segment difference of the package substrate 11, the first base substrate 14 is designed with a recess the depth of which is larger than or equal to the thickness of the sheet-like desiccant 11, and the sheet-like desiccant 11 is attached in the recess. The lower substrate is an array substrate 2 comprising thin film transistors (TFTs), wherein the array substrate 2 comprises a second base substrate 20 evaporated with an OLED device 21. Sealing frame glue 3 is used for bonding and fixing the array substrate 2 and the package substrate 1 so as to achieve a sealed structure for the OLED device, thus blocking water and oxygen in air contacting with the OLED device. In the formed structure, the sheet-like desiccant 11 is in a region on the first base substrate 14 corresponding to the OLED device 21, that is, the region on the first base substrate 14 for the sheet-like desiccant 11 corresponds to the region on the second base substrate 20 for the OLED device 21. Thus, in order to make the sheet-like desiccant 11 not directly contacts with the OLED device 21, it is also required that the first base substrate 14 is designed with a recess the depth of which is larger than or equal to the thickness of the sheet-like desiccant 11 and the sheet-like desiccant 11 should be attached in the recess, so that reasonable space is reserved for the OLED device 21 after the package substrate 1 and the array substrate 2 are aligned and assembled into a cell. The main component of the sheet-like desiccant 11 may be calcium oxide, strontium oxide, etc. whose role is to absorb the water and oxygen in the sealed space between the array substrate 2 and the package substrate 1 after the two substrates are aligned and assembled into a cell, so as to extend the life of the OLED device. It should be understood that, although FIG. 1 shows only one OLED device 21, this OLED device actually represents multiple OLED devices each of which can independently emit light.

The applicant found at least the following problems in the prior art: the recess in the package substrate is required to have a certain depth, resulting in a great increase in the total thickness of the package substrate, which will affect the lightweight requirement for the final product; methods such as etching, etc. are needed to prepare the recess, and the cost is high.

### SUMMARY

Technical problems to be solved by the present invention are: cost for manufacturing the package substrate with a recess is high; and total thickness of the package substrate is large, resulting that it is difficult to achieve a lightweight OLED display panel and display apparatus.

The first objective of the present invention is to provide a package substrate with low cost and small thickness, by means of which a lightweight OLED display panel can be achieved.

To achieve the above objective, the present invention provides a package substrate for packaging OLED devices, comprising: a first base substrate which can be made of organic material or inorganic material such as glass, quartz, etc.; desiccant layer provided on the first base substrate, which comprises desiccant particles and a glue layer for fixing the desiccant particles.

As an example, the desiccant layer is provided on the regions of the first base substrate, which do not correspond to OLED devices.

As an example, the glue layer is photo-curable glue layer or heat-curable glue layer.

As an example, the thickness of the glue layer is between 10 μm and 20 μm.

As an example, the desiccant particles are spherical desiccant particles, the diameters of which are between 0.04 mm and 0.10 mm.

As an example, the desiccant particles are calcium oxide particles or strontium oxide particles.

The present invention adopts desiccant particles instead of sheet-like desiccant layer and the desiccant particles are adhered and fixed to the first base substrate by a glue layer, thus there could be no recess in the package substrate of the present invention, thereby the cost for manufacturing the package substrate of the present invention is low, the thickness thereof is reduced so that it is easy to achieve a lightweight OLED display panel which is packaged with the package substrate of the present invention.

The second objective of the present invention is to provide an OLED display panel with low cost, small thickness and light weight.

To achieve the above objective, the present invention provides an OLED display panel comprising the above package substrate, further comprising: an array substrate comprising OLED devices, wherein the array substrate and the package substrate are aligned and assembled into the OLED display panel.

As an example, the array substrate and the package substrate are bonded and fixed by sealing frame glue.

As an example, spacers are adhered and fixed on the sealing frame glue to support a cell thickness of the OLED display panel.

As an example, the array substrate comprises: a second base substrate; OLED devices formed on the surface of the second base substrate, wherein the OLED devices and the desiccant layer are located inside the OLED display panel.

As an example, a barrier layer is formed on the surface of each of the OLED devices.

As an example, the barrier layer is silicon nitride film, the thickness of which is between 8000 Å and 12000 Å.

The OLED display panel of the present invention employs the above package substrate, thus the cost thereof is low and the thickness thereof is small so that a lightweight OLED display panel is achieved.

The third objective of the present invention is to provide a method for manufacturing an OLED display panel with low cost, small thickness and light weight.

To achieve the above objective, the present invention provides a method for manufacturing an OLED display panel, comprising: forming a desiccant layer on a first base substrate to prepare a package substrate, wherein first forming a glue layer on the first base substrate, then adhering desiccant particles onto the glue layer; forming OLED devices on a second base substrate to prepare an array substrate; and aligning and assembling the array substrate and the package substrate to form the OLED display panel, wherein the desiccant layer and the OLED devices are located inside the OLED display panel.

As an example, the array substrate and the package substrate are bonded and fixed by sealing frame glue.

As an example, spacers are adhered and fixed on the sealing frame glue to support a cell thickness of the OLED display panel.

As an example, the step of forming a glue layer on the first base substrate comprises: forming the glue layer on the first base substrate by screen printing process.

As an example, the step of forming a glue layer on the first base substrate comprises: forming the glue layer on the regions of the first base substrate, which do not correspond to the OLED devices.

As an example, the step of adhering the desiccant particles onto the glue layer comprises: spraying the desiccant particles onto the glue layer by dry-type dispensing, wherein nitrogen atmosphere is used during the dry-type dispensing, and the concentrations of both of the water and oxygen in the nitrogen atmosphere are less than 1 ppm.

As an example, a barrier layer is formed on the surface of each of the OLED devices before the package substrate and the array substrate are aligned and assembled.

In the above method for manufacturing an OLED display panel, the desiccant layer is directly formed on the first base substrate to prepare a package substrate without a recess, thus an OLED display panel with low cost, small thickness and light weight can be achieved.

The fourth objective of the present invention is to provide a display apparatus with low cost, small thickness and light weight.

To achieve the above objective, the present invention provides a display apparatus comprising the above OLED display panel.

The display apparatus of the present invention employs the above OLED display panel, thus a display apparatus with low cost, small thickness and light weight can be achieved.

### BRIEF DESCRIPTION OF THE DRAWINGS

FIG. 1 is a structure diagram of a conventional package substrate with a recess.

FIG. 2 is a structure diagram of a package substrate according to embodiment of the present invention.

FIG. 3 is a cross-section diagram of FIG. 2 along the direction A-A.

FIG. 4 is a structure diagram of another package substrate according to embodiment 1 of the present invention.

FIG. 5 is a cross-section diagram of FIG. 4 along the direction B-B.

FIG. 6 is a structure diagram of an OLED display panel according to embodiment 2 of the present invention.

FIG. 7 is a cross-section diagram of FIG. 6 along the direction C-C.

FIG. 8 is a flow diagram of a method for manufacturing an OLED display panel according to embodiment 3 of the present invention.

FIG. 9 is a distribution diagram of thickness of glue formed by screen printing process according to embodiment 3 of the present invention,

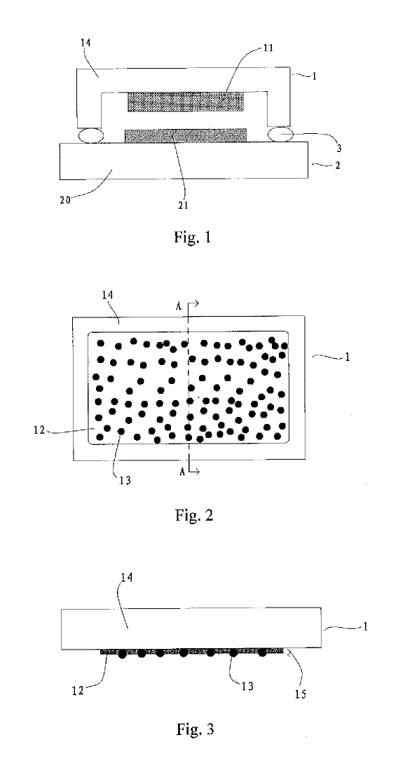

### REFERENCE SIGNS

1, package substrate; 2, array substrate; 3, sealing frame glue;
11, sheet-like desiccant; 12, glue layer; 13, desiccant particles;
14, first base substrate; 15, desiccant layer; 20, second base substrate;
21, OLED device; 22, barrier layer.

### DETAILED DESCRIPTION OF THE PREFERRED EMBODIMENTS

The technical solution of the present invention will be further described below in details with reference to the drawings and the embodiments.

### Embodiment 1

The present embodiment provides a package substrate for packaging OLED devices, comprising: a first base substrate; a desiccant layer provided on the first base substrate, wherein the desiccant layer comprises desiccant particles and a glue layer for fixing the desiccant particles.

In the package substrate of the present embodiment, the desiccant layer is directly provided on the first base substrate to achieve the same drying effect as that achieved by the sheet-like desiccant in the prior art, thus the sheet-like desiccant in the prior art is replaced by the desiccant layer of the present embodiment so that the recess for adhering the sheet-like desiccant is not necessary for the package substrate of the present embodiment, resulting in a reduced cost of production, a reduced thickness of the package substrate, and of course a lightweight OLED display panel.

The specific structure of the package substrate according to the present embodiment is shown in FIG. 2 and FIG. 3. As shown in FIG. 2 and FIG. 3, the package substrate comprises a first base substrate 14 provided with a desiccant layer 15 thereon, wherein the desiccant layer 15 mainly comprises two parts of desiccant particles 13 and a glue layer 12 for fixing the desiccant particles 13.

It can be seen from FIG. 2 and FIG. 3, there is no recess provided in the package substrate 1, and the desiccant layer 15 is directly provided on the first base substrate 14 rather than adhered in a recess. It can be understood that, in such a structure, in order to achieve a small total thickness of the package substrate 1, a small thickness of the desiccant layer 15 is required, that is to say, both of the thickness of the glue layer 12 and the size of the desiccant particles 13 should be small.

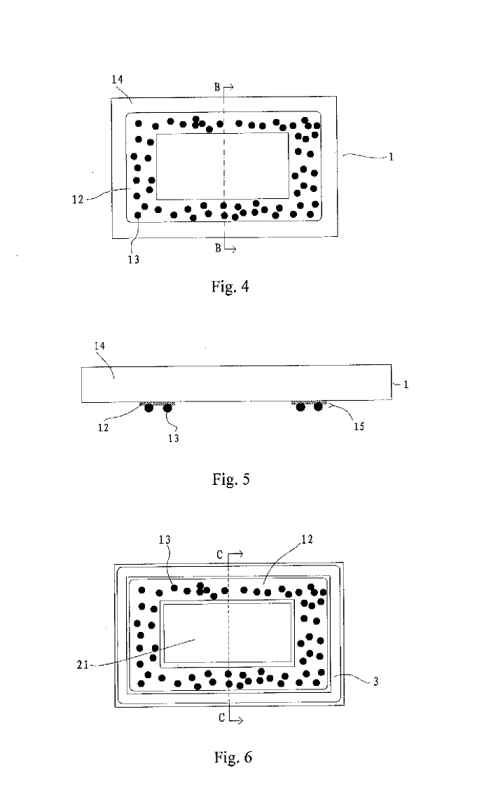

As an example, the desiccant layer 15 is provided on the region of the first base substrate 14, which does not correspond to the OLED device 21. As shown in FIG. 4 and FIG. 5, the glue layer 12 is provided on the region of the first base substrate 14, which does not correspond to the OLED device 21. The reason for this is to make that there is no desiccant layer blocking light on the region of the package substrate 1 corresponding to the OLED device 21 on the array substrate 2, thereby the OLED device 21 can be made into either top-emitting OLED device or bottom-emitting OLED device while packaged by the package substrate 1, eliminating the limitation that the OLED device 21 can only be made into bottom-emitting OLED device while employing the sheet-like desiccant 11 in the prior art. Meanwhile, the design that the glue layer 12 is provided on the region of the first base substrate 14, which does not correspond to the OLED device 21, makes the desiccant particles 13 as far away from the OLED device 21 as possible, preventing the desiccant particles 13 from directly contacting with the OLED device 21 to damage the OLED device 21.

Should be noted that, in FIG. 4 and FIG. 5, the desiccant layer 15 is provided on the periphery of the first substrate 14 in that water and oxygen having adverse effects to the OLED device 21 may enter from the periphery positions. That is, it will help the desiccant particles 13 in the desiccant layer 15 to absorb entered water and oxygen by providing the desiccant layer 15 on the periphery of the first substrate 14, preventing water and oxygen from entering and thus protecting the OLED device 21.

Also should be noted that, the specific distribution position of the desiccant layer 15 can be determined according to the amount of the desiccant required in a product. If the size of the product is small, as shown in FIG. 4 and FIG. 5, the desiccant layer 15 can only be provided on the non-display area surrounding the first base substrate 14. If the size of the product is large, the desiccant layer 15 can also be provided on the regions between the separated OLED devices 21.

As an example, the adhesive employed by the glue layer 12 is photo-curing adhesive or heat-curing adhesive.

As an example, the thickness of the glue layer 12 is between 10 μm and 20 μm. It is not difficult to understand that, the smaller the thickness of the glue layer 12 is, the smaller the thickness of the desiccant layer 15 is, the smaller the total thickness of the package substrate 1 will be.

Should be noted that, the desiccant layer 15 can comprise various shapes of desiccant particles 13, which will not be limited here. As an example, the desiccant particles 13 are spherical desiccant particles the diameters of which are between 0.04 mm and 0.10 mm. The reason for using spherical desiccant particles is that large surface area of spherical desiccant particles will help absorb water and oxygen, so as to meet the permeability requirements to water and oxygen for OLED devices 21. Meanwhile, using spherical desiccant particles will help the desiccant particles to be uniformly distributed in the desiccant layer 15 while being drying-type dispensed.

Further, the reason for selecting the diameter of the spherical desiccant particles between 0.04 mm and 0.10 mm is that the spherical particles of this size can be sprayed directly on the glue layer 12 of the package substrate 1 through the existing dry-type dispensing process, and the dry-type dispensing equipment is the same as a spacer dispensing equipment. That is, the spherical desiccant particles with diameter between 0.04 mm and 0.10 mm can be dispensed through existing equipment, reducing the production cost of the package substrate.

As an example, the desiccant particles 13 are calcium oxide particles or strontium oxide particles.

There is no recess in the package substrate 1 of the present embodiment, and the desiccant layer 15 is directly provided on the first base substrate 14, resulting in a low cost of production, a reduced thickness after aligning and assembling the array substrate 2 and the package substrate 1 and a lightweight OLED display panel packaged with the package substrate 1.

### Embodiment 2

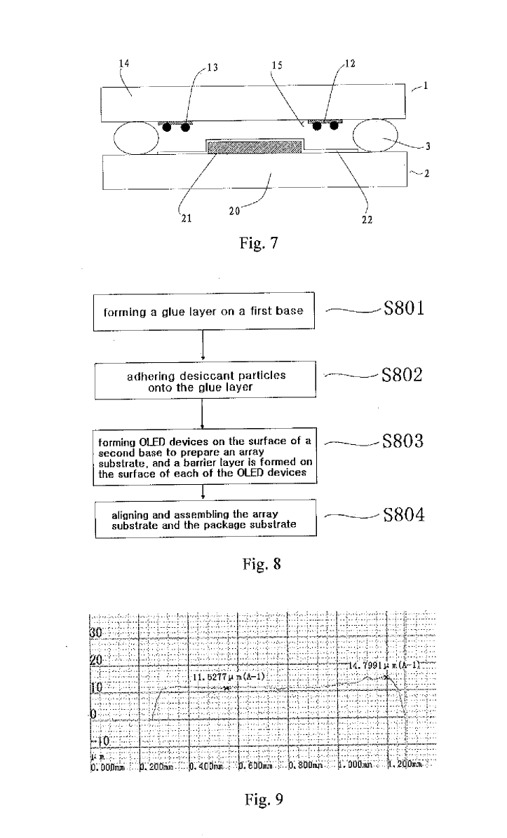

The present embodiment provides an OLED display panel comprising the above package substrate 1, further comprising: an array substrate 2 which is aligned and assembled with the package substrate 1 to form the OLED display panel, wherein the array substrate 2 comprises a second base substrate 20 provided with OLED devices 21 thereon, the OLED devices 21 and the desiccant layer 15 are inside the display panel, as shown in FIG. 6 and FIG. 7. Of course, the number of the OLED devices 21 can be determined according to the specific requirement of the OLED display panel.

FIG. 6 is a structure diagram of the OLED display panel according to the present embodiment. As shown in FIG. 6, a circle of sealing frame glue 3 is provided at the edge of the package substrate 1 for aligning and assembling the package substrate 1 and the array substrate 2. The glue layer 12 is provided at the inner side of the sealing frame glue 3. The desiccant particles 13 are adhered on the glue layer 12. There is no glue layer 12 on the regions of the package substrate 1 corresponding to the OLED devices 21 on the array substrate 2, thus the display of this region will not be affected, thereby the OLED devices 21 can be made into either top-emitting OLED devices or bottom-emitting OLED devices.

As an example, spacers are adhered and fixed on the sealing frame glue 3 to support a cell thickness of the OLED display panel.

As an example, a barrier layer 22 is formed on the surface of each of the OLED devices 21. Should be noted that, function of the barrier layer 22 is to prevent water and oxygen from entering into OLED devices 21 and prevent the desiccant particles 13 (for example, the desiccant particles 12 released from the glue layer 12) from directly contacting with OLED devices 21.

As an example, the barrier layer 22 is silicon nitride film, the thickness of which is between 8000 Å and 12000 Å.

Obviously, the OLED display panel of the present embodiment further comprises other regular parts which will not be described in detail.

The above package substrate 1 without a recess is used to form the OLED display panel of the present embodiment, and the thickness of the desiccant layer 15 is small, resulting in a low cost of production and a lightweight OLED display panel. Meanwhile, the desiccant layer 15 is provided at a certain position so that the OLED devices 21 can be made into either top-emitting OLED devices or bottom-emitting OLED devices, eliminating the limitation that the OLED devices can only be made into bottom-emitting OLED device while employing the sheet-like desiccant 11 in the prior art.

### Embodiment 3

The present embodiment provides a method for manufacturing an OLED display panel, as shown in FIG. 7 and FIG. 8, comprising the following steps.

S801, forming a glue layer 12 on a first base substrate 14.

As an example, the step of forming a glue layer 12 on a first base substrate 14 comprises: forming a glue layer 12 on a first base substrate 14 through screen printing process.

The reason for selecting screen printing process to prepare the glue layer is that, as shown in FIG. 9, the cross-section of the glue layer 12 formed through screen printing process is trapezoidal, resulting that the desiccant particles 13 can be adhered well thereon and will not easily fall off, thus the probability that the released desiccant particles 13 produce adverse effects on the OLED devices 21 is reduced. Meanwhile, in actual production, a glue layer 12 with a thickness between 10 μm and 20 μm can be formed through screen printing process, which will meet the requirement for the small thickness of the glue layer 12. Of course, the glue layer 12 can also be made by using other processes, as long as desiccant particles 13 can be adhered and fixed by the glue layer 12.

As an example, the step of forming a glue layer 12 on a first base substrate 14 comprises: forming a glue layer 12 on the regions of the first base substrate 14, which do not correspond to OLED devices.

S802, adhering desiccant particles 13 onto the glue layer 12.

As an example, the step of adhering desiccant particles 13 onto the glue layer 12 comprises: spraying the desiccant particles onto the glue layer by dry-type dispensing, wherein nitrogen atmosphere is used during the dry-type dispensing, and concentrations of both of water and oxygen in the nitrogen atmosphere are less than 1 ppm.

The dry-type dispensing equipment employed during the dry-type dispensing can uniformly spray desiccant particles 13 onto the glue layer 12, which helps production. The dry-type dispensing equipment is the same as a spacer dispensing equipment. The spacer dispensing equipment is an existing equipment and can stably perform operation, thus it will simple and easy to spray desiccant particles 13 onto the glue layer 12 using this type equipment.

Further should be noted that, some desiccant particles 13 may be sprayed onto the first base substrate 14 while spraying desiccant particles 13 onto the glue layer 12 through dry-type dispensing. In this case, after spraying the desiccant particles 13, curing the glue layer 12 to adhere and fix the desiccant particles 13 on the glue layer 12, then blow nitrogen with a certain pressure to clear the first base substrate 14, the desiccant particles 13 outside the glue layer 12 will be removed so that all the remaining desiccant particles 13 are adhered to the glue layer 12, thus it is assured that no desiccant particles 13 will directly contact with the OLED devices 21.

S803, forming OLED devices 21 on the surface of a second base substrate 20 to prepare an array substrate 2.

As an example, a barrier layer 22 is formed on the surface of each of the OLED devices 21.

Specifically, various methods can be used for forming the OLED devices 21 on the surface of the second base substrate 20 to prepare the array substrate 2 and forming the barrier layer 22 on the surface of each of the OLED devices 21, which will not be limited here.

For example, the OLED devices 21 can be formed on the surface of the second base substrate 20 through evaporation process. A layer of silicon nitride film with a thickness of 10000 Å can be deposited on the surface of each of the OLED devices 21 as the barrier layer 22. A silicon nitride film with such thickness can be obtained by adopting the technology such as existing low-temperature chemical vapor deposition, etc.

Should be noted that, the barrier layer 22 can effectively prevent water and oxygen from entering into the OLED devices 21, increasing the life of the OLED devices 21. Meanwhile, the barrier layer 22 can prevent the desiccant particles 13 from directly contacting with the OLED devices, avoiding damage of the OLED devices.

Further should be noted that, it is not necessary that the steps of forming OLED devices 21 on the surface of the second base substrate 20 and depositing a barrier layer 22 on the surface of each of the OLED devices 21 are after S801 and S802, as long as they are completed before aligning and assembling the array substrate 2 and the package substrate 1.

S804, aligning and assembling the array substrate 2 and the package substrate 1. Obviously, the desiccant layer 15 and the OLED devices 21 are inside the OLED display panel.

As an example, the array substrate 2 and the package substrate 1 are bonded and fixed by sealing frame glue 3.

As an example, spacers are adhered and fixed on the sealing frame glue 3 to support a cell thickness of the OLED display panel.

Of course, the method for manufacturing an OLED display panel of the present embodiment further comprises other regular steps, which are not limited here.

In the method for manufacturing an OLED display panel of the present embodiment, the desiccant layer 15 is directly formed on the first base substrate 14 without using the package substrate 1 with a recess, resulting in a low cost of production and a lightweight OLED display panel with a small thickness.

### Embodiment 4

The present embodiment provides a display apparatus, comprising the above OLED display panel.

The display apparatus may be a phone, navigator, tablet computer, notebook computer, monitor, etc.

The display apparatus of the present embodiment comprises the above OLED display panel, resulting a low cost of production, a lightweight display apparatus with a small thickness.

It should be understood that, the above implementations are only used to explain the principle of the present invention, but not to limit the present invention, the person skilled in the art can make various variations and modifications without departing from the spirit and scope of the present invention, therefore, all equivalent technical solutions fall within the scope of the present invention, and the protection scope of the present invention should be defined by the claims.

1. A package substrate for packaging OLED devices, comprising:
a first base substrate;
a desiccant layer provided on the first base substrate, which comprises desiccant particles and a glue layer for fixing the desiccant particles.

2. The package substrate according to claim 1, wherein the desiccant layer is provided on the regions of the first base substrate, which do not correspond to OLED devices.

3. The package substrate according to claim 1, wherein the glue layer is photo-curable glue layer or heat-curable glue layer.

4. The package substrate according to claim 1, wherein the thickness of the glue layer is between 10 μm and 20 μm.

5. The package substrate according to claim 1, wherein the desiccant particles are spherical particles.

6. The package substrate according to claim 5, wherein the diameters of the spherical particles are between 0.04 mm and 0.10 mm.

7. The package substrate according to claim 1, wherein the desiccant particles are calcium oxide particles or strontium oxide particles.

8. An OLED display panel, comprising:
a package substrate for packaging OLED devices, which comprises a first base substrate and a desiccant layer provided on the first base substrate, wherein the desiccant layer comprises desiccant particles and a glue layer for fixing the desiccant particles; and
an array substrate comprising OLED devices,
wherein the array substrate and the package substrate are aligned and assembled into the OLED display panel.

9. The OLED display panel according to claim 8, wherein the array substrate and the package substrate are bonded and fixed by sealing frame glue.

10. The OLED display panel according to claim 9, wherein spacers are adhered and fixed on the sealing frame glue to support a cell thickness of the OLED display panel.

11. The OLED display panel according to claim 8, wherein the array substrate comprises a second base substrate, and the OLED devices are formed on the surface of the second base substrate, and
wherein the OLED devices and the desiccant layer are inside the OLED display panel.

12. The OLED display panel according to claim 11, wherein a barrier layer is formed on the surface of each of the OLED devices.

13. The OLED display panel according to claim 12, wherein the barrier layer is silicon nitride film.

14. The OLED display panel according to claim 13, wherein the thickness of the silicon nitride film is between 8000 Å and 12000 Å.

15. A method for manufacturing an OLED display panel, comprising:
forming a desiccant layer on a first base substrate to prepare a package substrate, wherein first forming a glue layer on the first base substrate, then adhering desiccant particles onto the glue layer;
forming OLED devices on a second base substrate to prepare an array substrate; and
aligning and assembling the array substrate and the package substrate to form the OLED display panel,
wherein the desiccant layer and the OLED devices are inside the OLED display panel.

16. The method for manufacturing an OLED display panel according to claim 15, wherein the array substrate and the package substrate are bonded and fixed by sealing frame glue; and
wherein spacers are adhered and fixed on the sealing frame glue to support a cell thickness of the OLED display panel.

17. (canceled)

18. The method for manufacturing an OLED display panel according to claim 15, wherein the step of forming a glue layer on the first base substrate comprises:
forming the glue layer on the first base substrate by screen printing process.

19. The method for manufacturing an OLED display panel according to claim 15, wherein the step of forming a glue layer on the first base substrate comprises:
forming the glue layer on the regions of the first base substrate, which do not correspond to the OLED devices.

20. The method for manufacturing an OLED display panel according to claim 15, wherein the step of adhering the desiccant particles onto the glue layer comprises:
spraying the desiccant particles onto the glue layer by dry-type dispensing,
wherein nitrogen atmosphere is used during the dry-type dispensing, and the concentrations of both of the water and oxygen content in the nitrogen atmosphere are less than 1 ppm.

21. The method for manufacturing an OLED display panel according to claim 15, wherein a barrier layer is formed on the surface of each of the OLED devices before the package substrate and the array substrate are aligned and assembled.

22. (canceled)
